(19) United States
(12) Patent Application Publication
(10) Pub. No.: US 2009/0072313 A1
(43) Pub. Date: Mar. 19, 2009

(54) HARDENED TRANSISTORS IN SOI DEVICES

(75) Inventors: Jin Cai, Cortlandt Manor, NY (US); Wilfried E. Haensch, Somers, NY (US); Tak H. Ning, Yorktown Heights, NY (US); Philip J. Oldiges, LaGrangeville, NY (US); Ghavam G. Shahidi, Pound Ridge, NY (US)

Correspondence Address: CAREY, RODRIGUEZ, GREENBERG & PAUL, LLP, 950 PENINSULA CORPORATE CIRCLE, SUITE 3020, BOCA RATON, FL, 33487, US

(73) Assignee: INTERNATIONAL BUSINESS MACHINES CORPORATION, Armonk, NY (US)

(21) Appl. No.: 11/857,569

(22) Filed: Sep. 19, 2007

(51) Int. Cl. H01L 27/12

(52) U.S. Cl. 257/351; 257/E27.112

(57) ABSTRACT

A series transistor device includes a series source, a series drain, a first constituent transistor, and a second constituent transistor. The first constituent transistor has a first source and a first drain, and the second constituent transistor has a second source and a second drain. All of the constituent transistors have a same conductivity type. The series source is the first source, and the series drain is the second drain. A drain of one of the constituent transistors is merged with a source of another of the constituent transistors.

### CROSS-REFERENCE TO RELATED APPLICATIONS

This application is related to U.S. application Ser. No. ______ (Attorney Docket No. YOR920070315US1 (006)) filed on Sep. 19, 2007, entitled APPARATUS AND METHOD FOR HARDENING LATCHES IN SOI CMOS DEVICES, incorporated herein by reference in its entirety.

### BACKGROUND OF THE INVENTION

1. Field of the Invention

The disclosure relates generally to transistor devices and, more specifically, to hardened transistors.

2. Description of the Related Art

Complementary Metal-Oxide-Semiconductor (CMOS) devices using Semiconductor-On-Insulator (SOI) usually have low drain-to-source breakdown voltage because of floating-body effect. Even for an SOI CMOS device with its device body electrically tied to the source, the breakdown voltage is still small compared to a corresponding bulk-semiconductor CMOS device because of the very large series resistance in the body of the SOI device. This low drain-to-source breakdown voltage of SOI CMOS devices severely limits the application of SOI CMOS technology.

Complementary Metal-Oxide-Semiconductor (CMOS) circuits are also susceptible to high-energy particles. Upon a CMOS device, such as an SOI transistor, being biased in the OFF state and a high-energy particle, e.g., an alpha particle, being incident in the device channel or body region, the high-energy particle can generate a large number of electron-hole pairs, causing a large transient current to flow between the source and the drain. This large transient current causes a device, which is biased in the OFF (or non-conducting state) to become momentarily conducting, and this conduction can momentary turn the transistor ON, which can cause an error to occur in the CMOS circuit. This is often called a soft-error or Single-Event Upset (SEU). These types of soft errors are a major reliability concern in modern circuits. Unless storage elements are protected, soft errors can cause unrecoverable loss of data and system crashes. Various sources of high energy particles, which lead to soft errors, include impurities in packaging materials, impurities present in back of the line interconnect, and cosmic rays.

FIG. 1 illustrates a conventional SOI transistor 10. The transistor 10 includes a source 12 and a drain 14 surrounding a body 24 and a gate 16. Isolation devices 18 electrically isolate the transistor 10, and the transistor 10 is formed over a buried oxide 20, which is positioned over a silicon substrate 22.

FIG. 2 illustrates a conventional latch 100. As used herein, a latch is a circuit topology with cross-coupled logic gates and a clocked feedback path, and a flip-flop is two latches used together in a Master-Slave configuration. The logic states of “clock” and “clock_not” are opposite of each other. Upon “clock”=1, Field Effect Transistors (FETs) 101, 102 are ON while FETs 104/105 are OFF. The latch 100 is written such that “true” ← “data.” Upon “clock”=0, FETs 101, 102 are OFF while FETs 104, 105 are ON. The latch 100 maintains its state via a pair of cross-coupled inverters formed by FETs 107, 108 and FETs 103, 106. The inverter formed by FETs 109, 110 drives external circuits. Assuming an initial state of “true”=0, FET 108 is OFF and FET 107 is ON while “comp”=1. The “comp”=1 drives FET 106 to ON and FET 103 to OFF.

Upon a high energy particle hitting, for example, the body of FET 108, which is in the OFF state, the higher energy particle raises the drain to source current such that FET 108 turns ON and node “comp” is pulled low to 0. The inverter formed by FETs 103, 106 reacts and drives its output node of “true” to a high value and the prior 0 state of node “true” is lost. Thus, the result from the impact of high energy particle is a loss of stored data.

Many different techniques have been employed to harden these transistors and circuits against soft errors. Techniques to address these soft errors include physically shielding the entire device from radiation. Logical techniques have also been employed to address SEU. For example, at a register level, parity bits are added to stored data and error correction codes are used to check for corrupted data. At the latch level, in which only a single bit of information is stored, three latches can be used to represent the same data and a 1 out of 3 majority circuit is used to read the data (i.e., ab+ac+bc). At the transistor level, redundant transistors/storage nodes may be employed and compared against one another. These techniques, however, can be expensive, in area on a chip, delay and/or power consumption, to employ. There is, therefore, a need for an improved transistor design that reduces SEU.

### BRIEF SUMMARY OF THE INVENTION

Embodiments of the invention provide a novel and non-obvious transistor device for reducing SEU. The series transistor device includes a series source, a series drain, a first constituent transistor, and a second constituent transistor. The first constituent transistor has a first source and a first drain, and the second constituent transistor has a second source and a second drain. All of the constituent transistors have a same conductivity type. The series source is the first source, and the series drain is the second drain. A drain of one of the constituent transistors is merged with a source of another of the constituent transistors. For example, the first drain is merged with the second source.

In another embodiment of the invention, the series transistor device is a SOI device, and the device bodies of all the constituent transistors are electrically isolated from one another. A third constituent transistor may be electrically positioned between the first constituent transistor and the second constituent transistor. At least two of the constituent transistors have separate gates that are directly electrically connected to one another. Also, at least two of the constituent transistors have a shared common gate. At least two of the constituent transistors have substantially different channel lengths than one another, and at least two of the constituent transistors have substantially different characteristics than one another. Alternatively at least two of the constituent transistors have substantially identical characteristics.

In another embodiment of the invention, an inverter circuit comprises a n-channel transistor device and a p-channel transistor device. An input is directly electrically connected to a gate of the n-channel transistor device and a gate of the p-channel transistor device, and at least one of the n-channel transistor device and the p-channel transistor device is a series transistor device. In certain aspects, the p-channel transistor device is the series transistor device, and in other aspects, the n-channel transistor device is the series transistor device. In further aspects, both the n-channel transistor device and the p-channel transistor device are series transistor devices.

Additional aspects of the invention will be set forth in part in the description which follows, and in part will be obvious from the description, or may be learned by practice of the invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE SEVERAL VIEWS OF THE DRAWINGS

The accompanying drawings, which are incorporated in and constitute part of this specification, illustrate embodiments of the invention and together with the description, serve to explain the principles of the invention. The embodiments illustrated herein are presently preferred, it being understood, however, that the invention is not limited to the precise arrangements and instrumentalities shown, wherein:

FIG. 1 is a cross-sectional view of a conventional transistor device;

FIG. 2 is a circuit schematic of a typical conventional latch;

FIG. 3 is a cross-sectional view of a series transistor having a merged node, in accordance with the inventive arrangements;

FIG. 4 is a cross-sectional view of a series transistor in which the drain of a first transistor is physically separate from the source of a second transistor, in accordance with the inventive arrangements;

FIGS. 5A and 5B are a cross-sectional views of a series transistor with three constituent transistors and two merged nodes with separate gates and a shared common gate, respectively, in accordance with the inventive arrangements;

FIG. 6 is a chart showing measured current-voltage characteristics of a series transistor having two constituent transistors and the measured current-voltage characteristics of the two constituent transistors;

FIGS. 7A and 7B are schematics, respectively, of a conventional n-channel FET and a p-channel FET;

FIGS. 8A and 8B are circuit schematics, respectively, of series n-channel FET and series p-channel FET, in accordance with the inventive arrangements;

FIG. 9 is a circuit schematic of a conventional inverter circuit;

FIG. 10 is a circuit schematic of an inverter circuit employing the series FETs, in accordance with the inventive arrangements;

FIG. 11 is a circuit schematic of an inverter circuit employing a conventional p-channel FET and a series n-channel FET, in accordance with the inventive arrangements;

FIG. 12 is a circuit schematic of an inverter circuit employing a conventional n-channel FET and a series p-channel FET, in accordance with the inventive arrangements;

FIG. 13 is a schematic, perspective view of a FinFET; and

FIG. 14 is a cross-sectional view of a series transistor with two constituent transistors with the constituent transistors having different channel lengths, in accordance with the inventive arrangements.

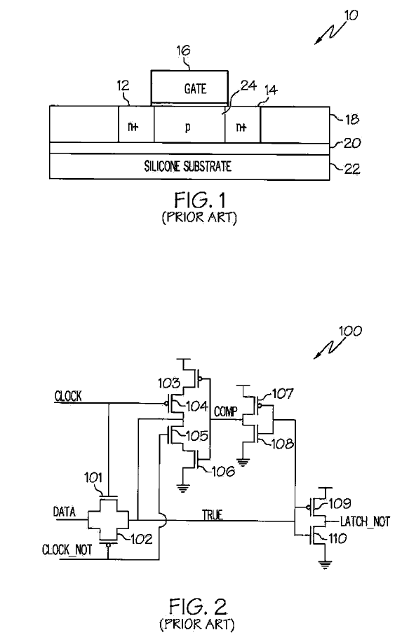

### DETAILED DESCRIPTION OF THE INVENTION

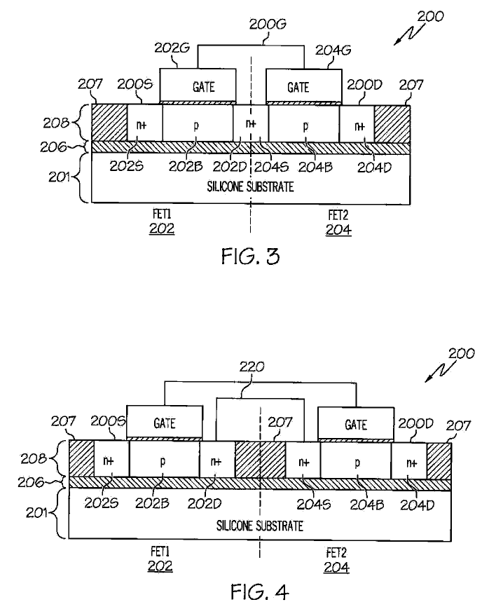

Referring to FIG. 3, a typical transistor structure associated with a Silicon-On-Insulator (SOI) device is illustrated. Specifically, an insulator (e.g., buried oxide 206) is positioned over a substrate (e.g., silicon) 201. A semiconductor layer 208 is then disposed over the buried oxide 206, and the transistor device is isolated, for example, using isolation oxides 207. However, in accordance with the inventive aspects, the transistor structure is a series SOI nFET 200. Although FIGS. 3-5 are discussed with regard to n-channel FETs, the disclosure is not limited in this manner. As is readily recognized, the same concepts can be applied to a series SOI pFET with constituent SOI pFETs.

The SOI device is not limited as to the type of material used to fabricate the device. For example, the semiconductor layer 208 and the substrate 201 can be formed from any semiconductor material suitable for forming a SOI device. Although silicon is currently the most commonly semiconductor material used to form SOI, other semiconductor materials include germanium, silicon-germanium alloys, and semiconductor materials that can be grown on top of silicon, germanium, or silicon-germanium alloys.

The series SOI nFET 200 includes two constituent SOI nFETs 202, 204 connected in series. In certain aspects, the drain region 202D of nFET 202 is merged with the source region 204S of nFET 204. The gates 202G, 204G of nFET 202 and nFET 204 are connected together to form the gate of the series SOI nFET 200. The SOI series nFET 200 includes a source 200S, which is also the source 202S of nFET 202; a drain 200D, which is the drain 204D of nFET 204; a gate 200G, which is common to both nFET 202 and nFET 204. The merged node 202D/204S, which represents the drain 202D of nFET 202 and the source 204S of nFET 204, is floating such that that node 202D/204S is not connected to any external node or externally-applied bias voltage.

The merged region 202D/204S can reach down to a buried oxide layer 206 to isolate the p-type device body 202B of nFET 202 from the p-type device body 204B of nFET 204. The source region 200S and the drain region 200D of the series SOI nFET 200 is shown reaching to the buried oxide 206; however, the SOI nFET 200 is not limited to this particular configuration. Oftentimes, in typical SOI CMOS devices, the semiconductor layer 208 used is sufficiently thin so that the source and drain regions 200S, 200D reach the buried oxide layer 206. Thus, in typical SOI CMOS devices, the floating merged node 202D/204S, which is the drain 202D of nFET 202 and the source 204S of nFET 204, can reach the buried oxide layer 204 without additional device fabrication process steps.

Referring to FIG. 4, in certain aspects of the series SOI nFET 200, the drain 202D of nFET 202 and the source 204S of nFET 204 are not necessarily merged as a single region. Instead, the drain 202D of nFET 202 and the source 204S of nFET 204 can be physically separated as long as the drain 202D of nFET 202 and the source 204S of nFET 204 are electrically connected together. For example, an isolation region 207 is positioned between the drain 202D of nFET 202 and the source 204S of nFET 204, yet the drain 202D of nFET 202 is connected to the source 204S of nFET 204 via an electrical line 220.

One of the differences between the series SOI nFET 200 illustrated in FIG. 3 and the series SOI nFET 200 illustrated in FIG. 4 involves the tradeoffs these respective devices provide. For example, referring to the device of FIG. 4, the two constituent SOI nFETs 202, 204 can be separated by a relatively great distance so that a SEU that effects one of the constituent SOI nFETs 202, 204 has a very low probability of affecting the other constituent SOI nFETs 202, 204, and this probability generally increases as the distance between the two constituent SOI nFETs 202, 204 decreases.

However, referring to the device of FIG. 3, as a result of the merged node 202D/204S and the closeness of the constituent SOI nFETs 202, 204, this device can be more space-efficient as compared to a series SOI nFET 200 in which the two constituent series SOI nFET 200 are separated. Moreover, since the node 202D/204S is merged, a line electrically connecting the drain 202D of nFET 202 to the source 204S of nFET 204 is not required, which decreases manufacturing requirements. Thus, the tradeoff between the series SOI nFET 200 illustrated in FIG. 3 and the series SOI nFET 200 illustrated in FIG. 4 involves trading space efficiency and possibly manufacturing efficiency for potentially greater resistance to SEU.

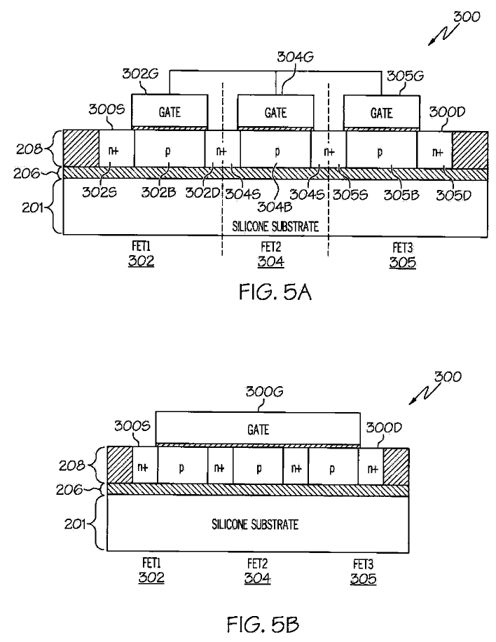

Referring to FIGS. 5A, 5B, the series SOI FET is not limited to a pair of constituent SOI FETs of the same conductivity type connected in series. Instead, the present SOI FET can include an arbitrary number of (i.e., two or more) constituent FETs of the same conductivity type connected in series. For example, as illustrated, an SOI n-channel series FET 300 includes three constituent SOI n-channel FETs 302, 304, 305 connected in series, with the source 302S of nFET 302 serving as the source of the series FET 300 and the drain 305D of nFET 305 serving as the drain of the series FET 300.

The drain region 302D of nFET 302 is merged with the source region 304S of nFET 304, and the merged region 302D/304S can reach down to the buried oxide layer 206 to electrically isolate the p-type body 302B of nFET 320 from the p-type body 304B of nFET 304. The drain region 304D of nFET 304 is merged with the source region 305S of nFET 305, and the merged region 304D/305S can reach down to the buried oxide layer 206 to electrically isolate the p-type body 304B of nFET 304 from the p-type body 305B of nFET 305. The gate electrodes 302G, 304G, 305G of all three constituent FETs are electrically connected together to form the gate of the series FET 300.

As described with reference to FIGS. 3 and 4, in terms of device operation and device characteristics, the source region 304S of nFET 304 and the drain region 302D of nFET 302 in FIGS. 5A, 5B are not necessarily merged. However, these nodes 302D, 304S are still electrically connected together. Moreover, an isolation region can be positioned between the drain region 302D of nFET 302 and the source region 304S of nFET 304. Similarly, the source region 305S of nFET 305 and the drain region 304D of nFET 304 are not necessarily merged. However, these nodes 304D, 305S are still electrically connected together, and an isolation region can be positioned between the drain region 304D of nFET 304 and the source region 305S of nFET 305.

Referring specifically to FIG. 5B, each of the constituent FETs 302, 304, 305 do not require an individual gate. Instead, as illustrated, two or more of the constituent FETs 302, 304, 305 can share a common gate 300G of the series FET 300. Although the common gate 300G has been illustrated with respect to three constituent FETs 302, 304, 305, as can be readily envisaged, a common gate can be used with a series FET 200 having two constituent FETs 202, 204, as illustrated in FIG. 3, or with more than three constituent FETs. Moreover, if a common gate is used, not all of the constituent FETs are required to employ the common gate. Instead, certain of the constituent FETs may have an individual gate.

In operation, the series SOI FET 200, 300 functions like a prior art SOI FET 10. A gate voltage, or gate-to-source voltage, turns ON the series FET 200, 300 and a drain voltage, or drain-to-source voltage, causes a current to flow between the source 200S/300S and the drain 200D/300D when the device 200/300 is in the ON state. The detailed current-voltage characteristics of a series FET 200, 300 depend on the particular device designs and/or device parameters of its individual constituent FETs 202/204, 302/304/305.

Although the individual constituent FETs 202/204, 302/304/305 may have the same characteristics (e.g., design and/or parameters), the disclosure is not limited in this manner. One or more of the individual constituent FETs 202/204, 302/304/305 may have substantially different designs and/or substantially different device parameters. For example, referring to FIGS. 3 and 4, FETs 202, 204 may have the same design, such as having the same gate insulator thickness, the same channel length (i.e., drain-to-source distance), the same p-type body region thickness and doping profile, and/or the same drain region doping profile. Alternatively, FETs 202, 204 may have different designs, such as having different channel lengths, different p-type body region thicknesses and doping profiles, and/or having different drain region doping profiles.

Moreover, the body region 202B of FET 202 may either be electrically shorted to its source region 202S or not electrically shorted to its source region 202S. Similarly, the body region 204B of FET 204 may either be electrically shorted to its source region 204S or not electrically shorted to its source region 204S. Furthermore, the body regions 202B, 204B of FETs 202, 204 may be either partially depleted (i.e., having a finite quasi-neutral body region) or fully depleted (i.e., having no quasi-neutral body region).

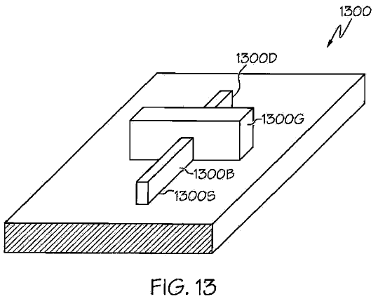

Referring to FIG. 13, although the series FET has been described with respect to a typical FET configuration, the series FET is not limited in this manner. For example, FIG. 13 illustrates a FinFET 1300, which can be employed as a constituent FET for the series FET. A FinFET 1300 is characterized by a “fin,” which constitutes the body region 1300B, and the dimensions of the fin 1300B determine the effective channel width of the FinFET 1300. Another example of a configuration of the constituent FET for the series FET is a Tri-gate FET. Structurally, a FinFET and Tri-gate FET are similar except that the width of the silicon body of a Tri-gate FET is wider than the width of the silicon body of a FinFET. As can be readily envisaged, other types of FET configurations may also be used with the series FET of the disclosure.

Current-Voltage Characteristics and Increased Drain-to-Source Breakdown Voltage

Relative to a regular SOI CMOS device 10, a series SOI device 200/300 has two distinctive properties. A series SOI CMOS device 200/300 may have a significantly larger drain-to-source breakdown voltage compared to a regular SOI CMOS device 10. Also, a series SOI CMOS device 200/300 is inherently insensitive to single-event upsets (SEU). The operation of a series n-channel FET having these properties is discussed herein. As previously noted, the same concepts can also be applied to a series p-channel FET.

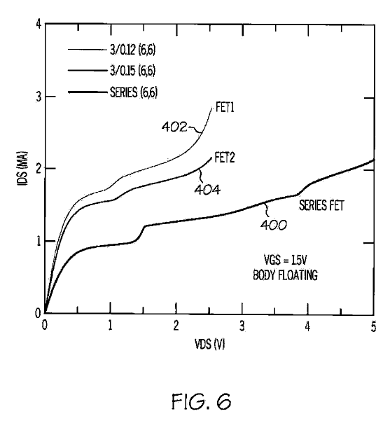

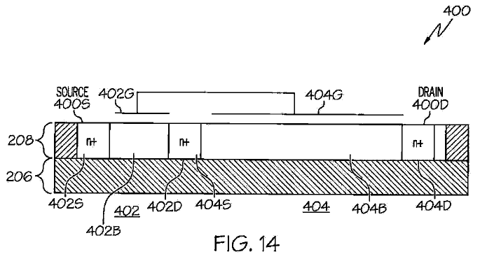

Referring to FIG. 6, the measured current-voltage characteristics of a series SOI nFET having two constituent SOI nFETs are illustrated. In this particular example, the nFETs 402, 404 have basically the same design except that the channel length of nFET 404 is substantially different (e.g., longer) than the channel length of nFET 402 (see FIG. 14). The current-voltage characteristics of nFET 402 and nFET 404, individually, are also illustrated for comparison. The gate voltage is 1.5 V for nFET 402, nFET 404 and for series nFET 400.

Referring to the current-voltage characteristics of nFET 402, for a given gate-to-source voltage, the current flowing in nFET 402 is a function of its drain-to-source voltage. Generally, the current increases as the drain-to-source voltage increases. The kink in the current-voltage characteristics, or the slight jump in current, at a drain-to-source voltage of about 1.0 V is caused by impact ionization occurring near the drain region 402D. Upon impact ionization occurring, electron-hole pairs are generated in the device body region 402B near the drain 402D. The holes flow towards the floating quasi-neutral p-type region of the body region 402B and are accumulated there. The accumulation of holes causes the quasi-neutral region of the device body 402B to become forward biased, which in turn causes the threshold voltage of nFET 402 to decrease and the source-to-drain current to increase. At a sufficiently large drain-to-source voltage, the device breaks down as indicated by the rapid rise in the source-to-drain current. For nFET 402, this occurs at about 2.3 V.

As to nFET 404, the current-voltage characteristics are basically the same as those of nFET 402, except that the current is slightly lower and the breakdown voltage is somewhat larger, both because of the longer channel length of nFET 404.

Referring to the current-voltage of the series SOI nFET 400, current continuity in the series SOI nFET 400 requires that the current flowing in nFET 404 be the same as the current flowing in nFET 402. Since the current flowing in nFET 402 is determined by the drain-to-source voltage of nFET 402, current continuity means that, for a given gate voltage, the voltage of the floating node (which is the drain of nFET 402 and the source of nFET 404) is determined by the current flowing in nFET 404. This property of the floating-node voltage plays a role in determining the drain-to-source breakdown voltage of the series SOI nFET 400.

Referring to the series SOI nFET 400, the drain-to-source voltage of the series SOI nFET 400 is the sum of the drain-to-source voltage of nFET 404 and the drain-to-source voltage of nFET 402. The kink in the current-voltage characteristics in the series SOI nFET 400 at about 1.5 V is caused by the impact ionization effect in nFET 404.

Impact ionization in the body 404B of nFET 404 generates electron-hole pairs in the body region 404B of nFET 404. The floating heavily doped n-type region, which is the merged drain 402D of nFET 402 and source 404S of nFET 404, blocks the holes generated by impact ionization in the device body 404B of nFET 404 from reaching the device body 402B of nFET 402. As a result, impact ionization in nFET 404 does not directly cause the threshold voltage of nFET 402 to be changed. Impact ionization in nFET 404 causes holes to be accumulated only in the p-type quasi-neutral region of the device body 404B of nFET 404, causing the threshold voltage of nFET 404 to be lowered and the current flowing in nFET 404 to be increased.

Current continuity, however, requires that any increase in the current flowing in nFET 404 be matched by the same increase in the current flowing in nFET 402. At a fixed gate voltage, the current flowing in nFET 402 may be increased if its drain-to-source voltage is increased. For a given drain-to-source voltage of the series SOI nFET 400, an increase in the drain-to-source voltage of nFET 402 results in a decrease in the drain-to-source voltage of nFET 404.

A decrease in the drain-to-source voltage of nFET 404 results in a reduction in the impact ionization in the body region 404B of nFET 404. In the series SOI nFET 400, the floating node 402D/404S between the body 402B of nFET 402 and the body 404B of nFET 404, which is the drain 402D of nFET 402 and source 404S of nFET 404, acquires a voltage that tends to reduce the impact ionization in the body region of nFET 404. This negative feedback mechanism causes the drain-to-source breakdown voltage of the series SOI nFET 400 to be significantly larger than that of nFET 402 or nFET 404. For the example series SOI nFET 400 shown in FIG. 6, the drain-to-source breakdown voltage is larger than 5 V.

Generally, the rate of impact ionization in a semiconductor region 208 can be reduced by reducing the maximum electric field in the region 208. In particular, the drain-to-source breakdown voltage of a FET can be increased by optimizing the device doping profile near the drain region to reduce the maximum electric field at or near its drain region. Therefore, the drain-to-source breakdown voltage of a series SOI device can be further increased by optimizing the doping profile near the drain region to reduce the maximum electric field at or near the drain region of one or more of its constituent devices.

Although not limited in this manner, SOI FETs are often used to fabricate power devices, where the devices operate at very large voltages and very large currents.

The present disclosure, therefore, is applicable to increase the drain-to-source breakdown voltages of power FETs.

Increased Immunity to Single-Event Upsets

A series SOI FET 200/300/400 is inherently less susceptible to SEU because of its built-in redundancy. This property can be understood by considering the series SOI nFET 200 illustrated in FIG. 3. Assuming that the series device 200 is biased in the OFF or non-conducting state, upon an alpha or some high-energy particle striking nFET 202, the particle can generate a sufficient number of electron-hole pairs in the device body 202B of nFET 202 to cause nFET 202 to become temporarily conducting. However, nFET 204 can remain non-conducting, and thus the series FET 200 is maintained in the OFF or non-conducting state.

Similarly, when an alpha or some high-energy particle strikes nFET 204, the particle can generate a sufficient number of electron-hole pairs in the device body 204B of nFET 204 to cause nFET 204 to become temporarily conducting. However, nFET 202 can remain non-conducting, and thus, the series FET 200 is maintained in the OFF or non-conducting state. A series SOI FET is susceptible to SEU only upon an event in which all of its constituent FETs 202, 204 are simultaneously hit by one or more high-energy particles. Thus, as long as at least one of the constituent FETs 202, 204 is not hit and remains non-conducting, the series FET 200 is also maintained in a non-conducting state.

Circuits Using Series SOI CMOS Devices

In operation, the series SOI CMOS devices 200/300/400 are comparable to traditional CMOS devices 10. Thus, the series SOI CMOS devices 200/300/400 may be used, in a circuit, in the same manner as a traditional CMOS device 10. Moreover, the series SOI CMOS devices may be used in circuits in combination with other series SOI CMOS devices, with traditional CMOS devices, or with both other series SOI CMOS devices and traditional CMOS devices. Furthermore, circuits employing both the series SOI CMOS devices and traditional CMOS devices may employ traditional SOI CMOS devices or bulk CMOS devices.

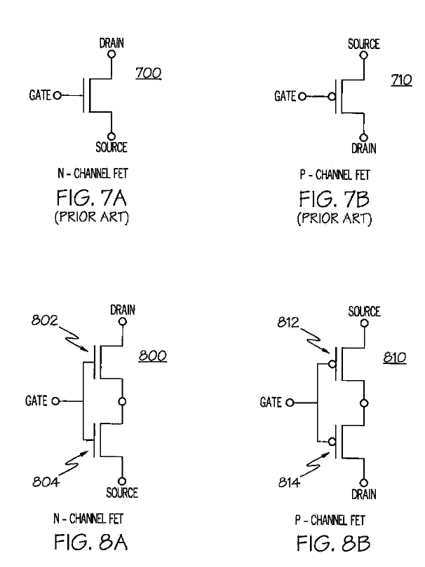

Referring to FIGS. 7A and 7B, commonly used circuit symbols for traditional CMOS devices 700, 710 are illustrated. For each CMOS device, the circuit symbol shows the connections to the gate, the drain, and the source of the device. Using the same convention for circuit symbols, the circuit symbols for the series SOI CMOS devices are illustrated in FIGS. 8A and 8B for the situation in which each series device 800, 810 consists of two devices 802/804, 812/814 of the same conductivity type connected in series. Similar to traditional regular CMOS devices 700, 710, each series device 800, 810 includes a connection to the gate, a connection to the source, and a connection to the drain.

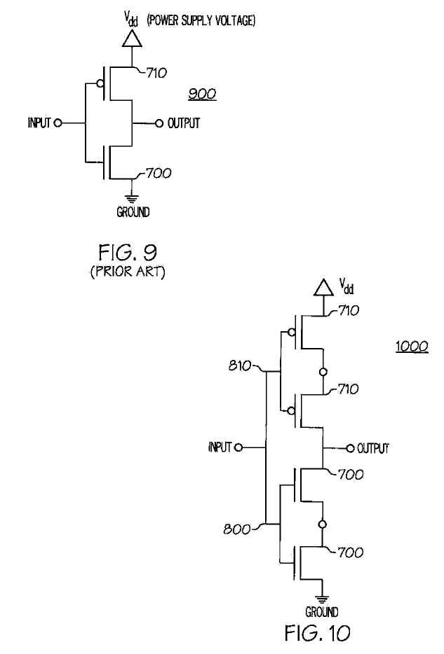

Referring to FIG. 9, a traditional CMOS inverter circuit 900 including one p-channel FET 710 and one n-channel FET 700 connected in series is illustrated. The source of the n-channel FET 700 is usually connected to ground, and the source of the p-channel FET 710 is usually connected to the circuit power supply. The gates of the two FETs 700, 710 are connected to the circuit input, and the drains of two FETs are connected to the circuit output. Upon the input voltage being low, the output voltage is high, and upon the input voltage being high, the output voltage is low.

Referring to FIG. 10, a CMOS inverter 1000 including one series SOI n-channel FET 800 and one series SOI p-channel FET 810 is illustrated. Each of the SOI series FET 800, 810 include two SOI FETs of the same conductivity type connected in series 700/700, 710/710. The source of the series n-channel FET 800 is connected to ground, and the source of the series p-channel FET 810 is connected to the circuit power supply. The gates of the two series FETs 800, 810 are connected to the circuit input, and the drains of two series FETs 800, 810 are connected to the circuit output. Upon the input voltage being low, the output voltage is high, and upon the input voltage being high, the output voltage is low.

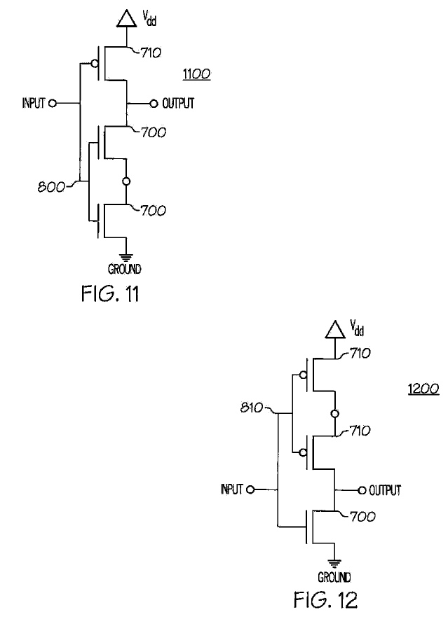

Referring to FIG. 11, a CMOS inverter 1100 including a series SOI n-channel FET 800 and a traditional p-channel FET 710 is illustrated. The series SOI n-channel FET 800 includes two traditional n-channel SOI FETs 700/700 connected in series. The source of the series n-channel FET 800 is connected to ground, and the source of the p-channel FET 710 is connected to the circuit power supply. The gates of the two FETs 710, 800 are connected to the circuit input, and the drains of the two FETs 710, 800 are connected to the circuit output. Upon the input voltage being low, the output voltage is high, and upon the input voltage being high, the output voltage is low.

Referring to FIG. 12, a CMOS inverter 1200 including a traditional n-channel FET 700 and a series SOI p-channel FET 810 is illustrated. The series SOI p-channel FET 810 includes two traditional p-channel SOI FETs 710/710 connected in series. The source of the n-channel FET 700 is connected to ground, and the source of the series p-channel FET 810 is connected to the circuit power supply. The gates of the two FETs 700, 810 are connected to the circuit input, and the drains of two FETs 700, 810 are connected to the circuit output. Upon the input voltage being low, the output voltage is high, and upon the input voltage being high, the output voltage is low.

Additional uses of series SOI devices and circuits using series SOI devices are described in related U.S. application Ser. No. ______ (Attorney Docket No. YOR920070315US1 (006)) filed on Sep. 19, 2007, entitled APPARATUS AND METHOD FOR HARDENING LATCHES IN SOI CMOS DEVICES, incorporated herein by reference in its entirety.

What is claimed is:

1. A series transistor device, comprising:
a series source;
a series drain;
a first constituent transistor having a first source and a first drain; and
a second constituent transistor having a second source and a second drain, wherein
all of the constituent transistors have a same conductivity type,
the series source is the first source,
the series drain is the second drain, and
a drain of one of the constituent transistors is merged with a source of another of the constituent transistors.

2. The device of claim 1, wherein the series transistor device is a SOI device.

3. The device of claim 1, wherein the first drain is merged with the second source.

4. The device of claim 1, further comprising a third constituent transistor electrically positioned between the first constituent transistor and the second constituent transistor.

5. The device of claim 1, wherein at least two of the constituent transistors have separate gates that are directly electrically connected to one another.

6. The device of claim 1, wherein at least two of the constituent transistors have a shared common gate.

7. The device of claim 1, wherein at least two of the constituent transistors have substantially different channel lengths than one another.

8. The device of claim 1, wherein at least two of the constituent transistors have substantially different characteristics than one another.

9. The device of claim 1, wherein at least two of the constituent transistors have substantially identical characteristics.

10. The device of claim 1, wherein the device bodies of all the constituent transistors are electrically isolated from one another.

11. A series transistor device, comprising:
a series source;
a series drain;
a first constituent transistor having a first source and a first drain; and
a second constituent transistor having a second source and a second drain, wherein
all of the constituent transistors have a same conductivity type,
the series source is the first source,
the series drain is the second drain, and
at least two of the transistors have substantially different characteristics than one another.

12. The device of claim 11, wherein at least two of the constituent transistors have substantially different channel lengths than one another.

13. An inverter circuit, comprising:
a n-channel transistor device; and
a p-channel transistor device, wherein
an input is directly electrically connected to a gate of the n-channel transistor device and a gate of the p-channel transistor device, and
at least one of the n-channel transistor device and the p-channel transistor device is a series transistor device.

14. The inverter circuit of claim 13, wherein the at least one series transistor device includes:
a series source;
a series drain;
a first constituent transistor having a first source and a first drain; and
a second constituent transistor having a second source and a second drain, wherein
all of the constituent transistors have a same conductivity type,
the series source is the first source,
the series drain is the second drain.

15. The inverter circuit of claim 14, wherein a drain of one of the constituent transistors is merged with a source of another of the constituent transistors.

16. The inverter circuit of claim 14, wherein at least two of the constituent transistors have substantially different characteristics than one another.

17. The inverter circuit of claim 14, wherein at least two of the constituent transistors have a shared common gate.

18. The inverter circuit of claim 13, wherein the p-channel transistor device is the series transistor device.

19. The inverter circuit of claim 13, wherein the n-channel transistor device is the series transistor device.

20. The inverter circuit of claim 13, wherein both the n-channel transistor device and the p-channel transistor device are series SOI transistor devices.
